(19) United States
(12) Patent Application Publication
(10) Pub. No.: US 2026/0190266 A1
(43) Pub. Date: Jul. 2, 2026

(54) Display Apparatus

(71) Applicant: LG Display Co., Ltd., Seoul (KR)

(72) Inventor: Kyoung-Jae Kim, Paju-si (KR)

(21) Appl. No.: 19/419,913

(22) Filed: Dec. 15, 2025

(30) Foreign Application Priority Data
Dec. 31, 2024 (KR) 10-2024-0201567

(51) Int. Cl. H05K 5/13; G02F 1/1333; G02F 1/16753; H05K 5/03; H10H 29/85; H10K 59/80

(52) U.S. Cl. CPC H05K 5/13; H05K 5/03; G02F 1/133325; G02F 1/133328; G02F 1/16753; H10H 29/8506; H10K 59/872

(57) ABSTRACT

The present disclosure provides a display apparatus. The display apparatus comprises a display panel, a plate of which a front surface is attached to the display panel, guide members disposed at both side ends of a rear surface of the plate to form a guide grooves between the guide member and the rear surface of the plate, a protrusion formed in the plate, a rear cover disposed at the rear surface of the plate, guide bars formed in both sides of the rear cover to be slidingly inserted into the guide grooves so as to assemble the plate and the rear cover, and a coupling

### CROSS-REFERENCE TO RELATED APPLICATIONS

This application claims the priority under 35 U.S.C. § 119(a) to the Republic of Korea Patent Application No. 10-2024-0201567, filed on Dec. 31, 2024, the entire contents of which are hereby expressly incorporated by reference into the present application.

### TECHNICAL FIELD

The present application generally relates to a display apparatus, and more specifically, for example, without limitation, to the display apparatus that is simple to assemble and may reuse a display panel.

### BACKGROUND

As information technology develops, various types of small and thin displays such as liquid crystal display devices, organic light emitting display devices, plasma display devices, micro-LED display devices, etc. have been proposed.

This display apparatus is assembled with various electronic devices such as a smartphone or a tablet PC. In particular, in recent years, the display apparatus is installed on a dashboard of a vehicle to provide various information about the vehicle, as well as to perform a function of navigation and various entertainment functions.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

The display apparatus is coupled to a user's set frame such as the vehicle by a double-sided tape. However, the inventors of the present application have realized that since it is difficult to separate the display apparatus from the set frame due to the double-sided tape, there is a limitation that it is difficult to reuse the display apparatus.

An object of the present application is to provide a display apparatus that is easy to assemble.

Another object of the present application is to provide a display apparatus capable of reusing a display module.

In order to achieve the object, a display apparatus according the present application includes a display panel, a plate disposed of which a front surface is attached to t the display panel, guide members disposed at both side ends of a rear surface of the plate to form a guide grooves between the guide member and the rear surface of the plate, a protrusion formed in the plate, a rear cover disposed at the rear surface of the plate, guide bars formed in the both sides of the rear cover to be slidingly inserted into the guide grooves so as to assemble the plate and the rear cover, and a coupling member for coupling the protrusion and the rear cover.

The plate and the guide member may be integrally formed, and the guide member may be connected to the upper end of the rear surface of the plate. At this time, an entrance of the guide grooves is formed under the plate so that the rear cover may be inserted into the guide groove from the bottom of the guide groove. The protrusion is formed in the upper end of the rear surface of the plate, and the coupling member may be a first screw penetrating the plate and an upper surface of the rear cover.

The entrance of the guide groove is formed above the plate so that the rear cover may be inserted into the guide groove from the top of the guide groove. At this time, the protrusion may be formed in a lower of the rear surface of the plate and the coupling member may be a second screw penetrating the plate and a lower surface of the rear cover. The second screw further penetrates the cover bottom.

It is to be understood that both the foregoing general description and the following detailed description are exemplary and explanatory and are intended to provide further explanation of the application as claimed.

Other systems, methods, features and advantages will be, or will become, apparent to one with skill in the art upon examination of the following figures and detailed description. It is intended that all such additional systems, methods, features and advantages are included within this description, fall within the scope of the present disclosure, and are protected by the following claims. Nothing in this section should be taken as a limitation on those claims. Further aspects and advantages are discussed below in conjunction with embodiments of the disclosure.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

FIG. 1 is a perspective view of a display apparatus according to the present application.

FIG. 2 is an exploded perspective view of a display module of the display apparatus according to a first embodiment of the present application.

FIG. 3 is a cross-sectional view illustrating the display panel of the display apparatus according to the first embodiment of the present application.

FIGS. 4A and 4B are views illustrating a plate of the display apparatus according to the present application.

FIG. 5 is the exploded perspective view illustrating a set frame of the display apparatus according to a first embodiment of the present application.

FIG. 6 is the view illustrating guide bars disposed on both side surfaces of a rear cover of the display apparatus according to the first embodiment of the present application.

FIGS. 7A and 7B are views illustrating that the display module is coupled to the rear cover in the display apparatus according to the first embodiment of the present application.

FIGS. 8A and 8B are views illustrating a coupling portion of the display module and the set frame of the display apparatus according to the first embodiment of the present application, respectively.

FIGS. 9A and 9B are the views illustrating the display module of the display apparatus according to a second embodiment of the present application.

FIGS. 10A and 10B are the views illustrating the coupling portion of the display module and the set frame of the display apparatus according to the second embodiment of the present application, respectively.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted or provided briefly herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical idea of the present disclosure.

In describing the components of the application, terms such as first, second, A, B, (a), (b), etc. may be used. These terms are only for distinguishing the elements from other elements, and the essence, order, or number of the elements are not limited by the terms. when it is described that a component is “connected” “coupled” or “attached” to another component, the component may be directly connected or attached to the other component, or indirectly connected or attached to the other component, without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the application may include the display apparatus itself such as the LCM, the OLED module, etc., and the application product including the LCM, the OLED module, or the like, or the set apparatus, which is the apparatus for end users.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Any implementation described herein as an “example” is not necessarily to be construed as preferred or advantageous over other implementations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, the present application will be described in detail with reference to the accompanying drawings.

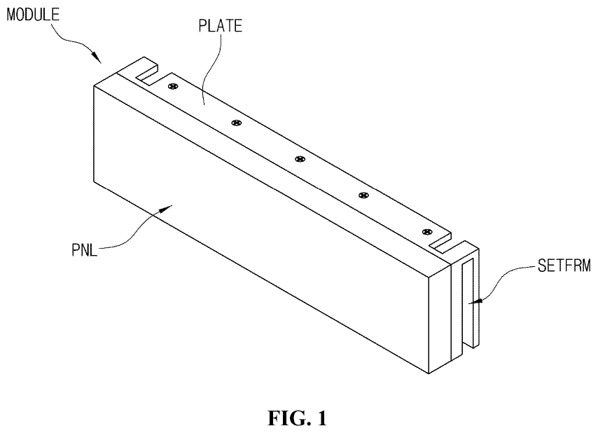

FIG. 1 is a perspective view of a display apparatus according to the present application.

As shown in FIG. 1, the display apparatus according to the present application includes a display module MODULE and a set frame SETFRM coupled to the display module MODULE.

The set frame SETFRM may be a set of electronic products to which the display module MODULE is coupled, that is, one frame of an external system. The electronic product set may include various electronic devices such as a smart phone, a laptop computer, a digital broadcasting terminal, a personal digital assistants (PDA), a portable multimedia player (PMP), a vehicle dashboard, a slate PC, a tablet PC, an ultra-book, a watch-type terminal, a smart glass, or a wearable device such as a head mounted display (HMD).

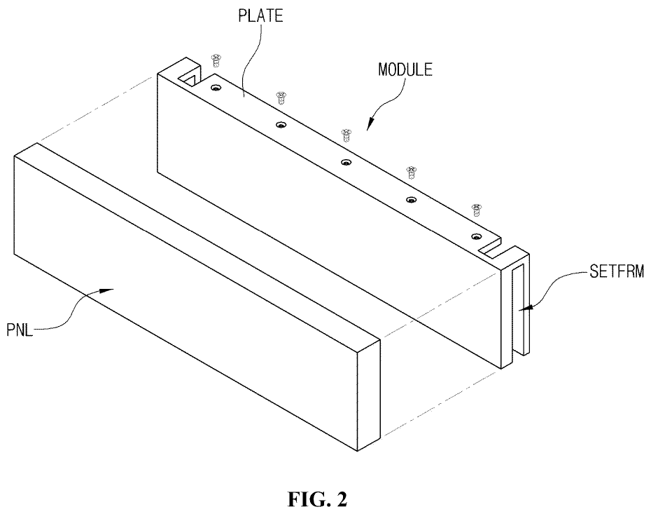

The display module MODULE may be coupled to the set frame SETFRM by various methods. In FIGS. 1 and 2, the set frame SETFRM may be coupled to the set frame SETFRM portion of the display module MODULE. As will be described later in detail, the display module MODULE and the set frame SETFRM may be coupled by a separate coupling means such as a screw, or may be assembled with and coupled to each other by structural features of the display module MODULE and the set frame SETFRM itself.

The display module MODULE and the set frame SETFRM may be coupled in a set. That is, the display module MODULE manufactured by the display module manufacturer is supplied to a set company, and the set company couples the supplied display module MODULE to the set frame SETFRM of the electronic device manufactured by the set company.

The display module MODULE is electrically connected to an external system through the set frame SETFRM so that image data of the external system is supplied to the display module MODULE.

FIG. 2 is an exploded perspective view of a display module MODULE of the display apparatus according to a first embodiment of the present application.

As shown in FIG. 2, the display module MODULE includes a display panel PNL on which an image is displayed and a plate PLATE disposed on a rear surface of the display panel PNL to support the display panel PNL. The display panel PNL may be attached to the plate PLATE by an adhesive.

Although not shown in the drawing, the display panel PNL may include a source printed circuit board. The source printed circuit board is electrically connected to the display panel PNL through a flexible circuit film so as to apply various signals to the display panel PNL. Various signal lines, circuit elements, and memory elements may be mounted on the source printed circuit board. For example, the circuit elements such as an image processing unit, a timing control unit, and a power supply unit may be mounted on the source printed circuit board.

Further, the source printed circuit board is connected to a control printed circuit board so that the display module (MODULE) may be electrically connected to the external system.

The display panel PNL includes a liquid crystal display panel, an organic light emitting display panel, a mini-LED display panel, an electrophoretic display panel, a micro-LED display panel, or the like, but is not limited thereto.

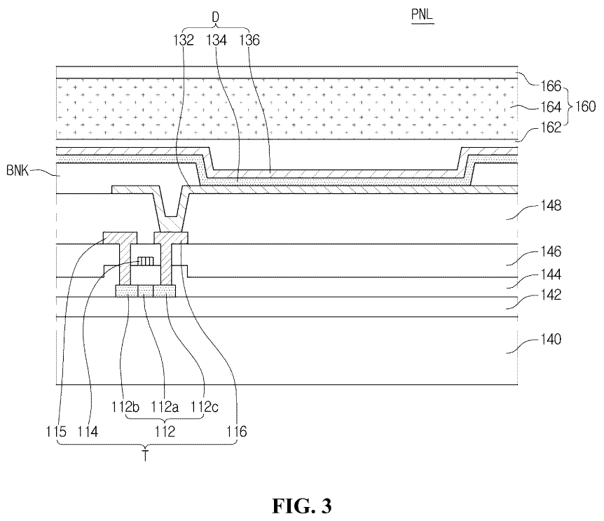

FIG. 3 is the diagram illustrating the display panel PNL of the display apparatus according to the present application. Hereinafter, the organic light emitting display panel is described as an example of the display panel PNL.

As shown in FIG. 3, a buffer layer 142 is formed on a substrate 140. The substrate 140 may be made of a hard material such as a glass or a plastic material, but not limited thereto. For example, the plastic material may include a polyimide, a polymethylmethacrylate, a polyethylene terephthalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

The buffer layer 142 may enhance adhering force between the substrate 140 and the layers thereon. Further, the buffer layer 142 may block various types of defects, such as alkali components flowing out from the substrate 140. In addition, the buffer layer 142 may delay diffusion of moisture or oxygen penetrating into the substrate 140.

The buffer layer 142 may be a single layer made of silicon oxide (SiOₓ) or silicon nitride (SiNₓ), or multi-layers thereof. When the buffer layer 142 is made of multiple layers, SiOₓ and SiNₓ may be alternately formed. The buffer layer 142 may be omitted based on the type and material of the substrate 140, the structure and type of the thin film transistor, and the like.

A thin film transistor T is formed on the buffer layer in each sub-pixel SP1, and SP2. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor T includes a semiconductor pattern 112 disposed on the buffer layer 142, a gate insulating layer 144 covering the semiconductor pattern 112, a gate electrode 114 on the gate insulating layer 144, an interlayer insulating layer 146 covering the gate electrode 114, and a source electrode 115 and a drain electrode 116 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-Gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers on both sides of the channel region 112a.

The gate insulating layer 144 may be formed of a single layer or multiple layers made of an inorganic material such as SiOₓ or SiNₓ, but is not limited thereto.

The gate electrode 114 is made of a metal. For example, the gate electrode 114 may be formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of an organic material such as photo-acryl, or the interlayer insulating layer 146 may formed of the single layer or the multiple layers made of an inorganic material such as SiOₓ or SiNₓ, but is not limited thereto. Further, the interlayer insulating layer 146 may be formed of the multi layers of the organic material layer and the inorganic material layer, but is not limited thereto.

The source electrode 115 and the drain electrode 116 are formed of the single layer or multiple layers made of a single metal or alloys of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Although not shown in drawing, a bottom shield metal layer may be disposed on the substrate 140 under the semiconductor pattern 112. The bottom shield metal layer alleviates or minimizes a backchannel phenomenon caused by charges trapped in the substrate 140 to reduce or prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate where the thin film transistor is disposed. The planarization layer 148 may be formed of an organic material such as photo-acrylic, but it is not limited thereto. The planarization layer 148 may include a plurality of layers including the inorganic layer and the organic layer.

A light emitting device D is disposed on the planarization layer 148. The light emitting device D includes a first electrode 132, a light emitting layer 134, and a second electrode 136. The light emitted from the light emitting layer 134 is output downward through the first electrode 132.

The first electrode 132 is formed of a single layer or multiple layers made of metals such as Ca, Ba, Mg, Al, and Ag, or alloys thereof.

A bank layer BNK is formed at the boundary between the sub-pixels on the planarization layer 148. The bank layer BNK may be a barrier wall to define sub-pixels. The bank layer BNK divides each sub-pixel to reduce or prevent light of a specific color output from adjacent pixels from being mixed and output.

The bank layer BNK is made of at least one material of the inorganic insulating material such as SiNₓ or SiOₓ, the organic insulating material such as benzocyclobutene, acrylic resin, epoxy resin, phenolic resin, polyamide resin, or a photosensitizer including a black pigment, but is not limited thereto.

The light emitting layer 134 is disposed in sub-pixels and may include an R-emitting layer that emits red light, a G-emitting layer that emits green light, and a B-emitting layer that emits blue light. Further, the light emitting layer may include a W-emitting layer that emits white light.

The light emitting layer 134 may include an organic light emitting layer, an inorganic light emitting layer, a nano-sized material layer, a quantum dot, a micro-LED light emitting layer, or a mini-LED light emitting layer, but is not limited thereto.

The light emitting layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the light emitting layer 134, and may be made of a transparent conductive material such as ITO (Indium Tin Oxide) or IZO (Indium Zinc Oxide), or a thin metal through which visible light is transmitted, but is not limited thereto.

Further, the light emitting device D may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulation layer 160 is formed over the second electrode 136 to encapsulate the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating the light emitting device D may oxidize the metal electrode. The encapsulation layer 160 blocks impurities such as oxygen and moisture from the outside to reduce or prevent defects of the light emitting device D and various electrodes.

The encapsulation layer 160 may include a first encapsulation layer 162, a second encapsulation layer 164, and a third encapsulation layer 166, but is not limited thereto. The encapsulation layer 160 may be formed of two layers or four or more layers.

The first encapsulation layer 162 and the third encapsulation layer 166 may be formed of the inorganic material such as SiOₓ, SiON, SiNₓ, or the like, and may further include the organic material between inorganic materials such as SiOₓ, SiON, or SiNₓ, but are not limited thereto. The second encapsulation layer 164 may be formed of the organic insulating material such as acrylic resin, epoxy resin, polyimide, polyethylene, or silicon oxycarbon (SiOC), but is not limited thereto. The third encapsulation layer 166 may be formed of a thin face seal metal, but is not limited thereto.

Although not shown in figure, a touch member may be disposed on the encapsulation layer 160. The touch member can detect external touch information using the user's finger or a touch pen.

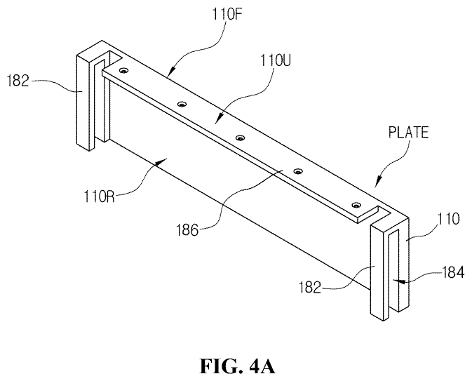

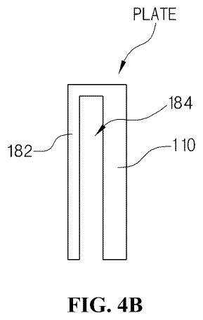

FIGS. 4A and 4B are the views illustrating the plate PLATE of the display apparatus according to the present application.

As shown in FIGS. 4A and 4B, the plate PLATE includes a base 110, a guide member 182 disposed at both ends of the rear surface 110R of the base 110, and a protrusion 186 disposed at the upper end of the rear surface 110R of the base 110. The display panel PNL is attached to the front surface 110F of the base 110, and the set frame SETFRM is coupled to the rear surface 110R.

The guide member 182 is formed in a bar shape which extends from the upper surface 110U of the base 110 and is spaced apart from the rear surface 110R by a predetermined distance. In this case, the guide member 182 is formed in a band shape having a small width and has the same or substantially same length as the base 110 in the vertical direction of the base 110. The guide groove 184 is formed between the guide member 182 and the rear surface 110R of the base 110.

The protrusion 186 is formed perpendicular to the rear surface 110R to protrude from the upper surface 110U of the base 110 toward the rear surface 110R. In this case, the protrusion 186 may be spaced apart from the guide member 182 by a predetermined distance.

The base 110, the guide member 182, and the protrusion 186 may be made of a metal such as aluminum, but are not limited thereto. In addition, the base 110, the guide member 182, and the protrusion 186 may be integrally formed, but may be formed separately.

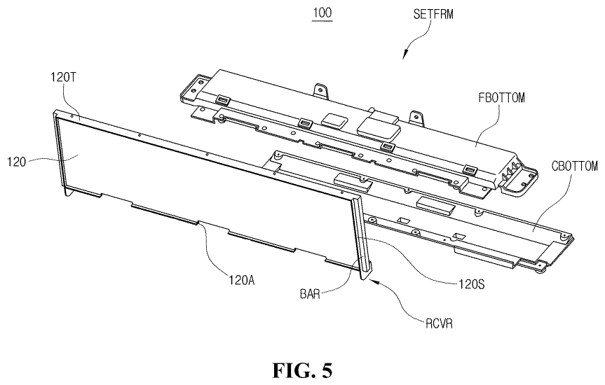

FIG. 5 is the exploded perspective view illustrating the set frame SETFRM of the display apparatus 100 according to the first embodiment of the present application.

As shown in FIG. 5, the set frame SETFRM includes a rear cover RCVR, a cover bottom CBOTTOM, and a frame bottom FBOTTOM.

The rear cover RCVR includes a base 120 in which the display module MODULE is coupled to the front surface thereof, and a coupling unit 120A formed under the base 120. The coupling unit 120A is formed perpendicular to the base 120 on the bottom surface of the base 120 and then coupled to the frame bottom FBTOOM. In this case, the coupling unit 120A of the rear cover RCVR may be coupled to the frame bottom FBTTOM by screws.

The rear cover RCVR may be formed of the metal such as aluminum, but is not limited thereto and may be formed of the organic material such as resin. In this case, the base 120 and the coupling unit 120A may be formed integrally or separately.

The cover bottom CBOTTOM is disposed under the frame bottom FBOTTOM to support the frame bottom FBOTTOM. The cover bottom CBOTTOM may be coupled to the frame bottom FBOTTOM. The cover bottom CBOTTOM and the frame bottom FBOTTOM may be made of the metal such as aluminum, but is not limited thereto

Meanwhile, the cover bottom CBOTTOM and the frame bottom FBOTTOM may be integrally formed. From another point of view, the frame bottom FBOTTOM may be omitted, and the rear cover RCVR may be directly coupled to the cover bottom CBOTTOM.

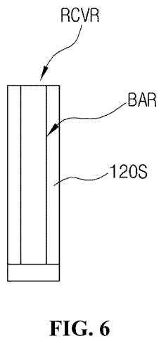

As shown in FIG. 6, the guide bars are formed on both side surfaces 120S of the base 120 of the rear cover RCVR. The guide bars BAR are formed to protrude from the surface of both side surfaces 120S along both side surfaces 120S of the base 120.

The guide bar BAR corresponds to the guide groove 184 of the plate PLATE of the display module MODULE. That is, the guide bar BAR is formed to have the same or substantially same width as the guide groove 184, and the guide bar BAR is inserted into the guide groove 184 so that the plate PLATE of the display module MODULE is coupled and fixed to the rear cover RCVR of the set frame SETFRM.

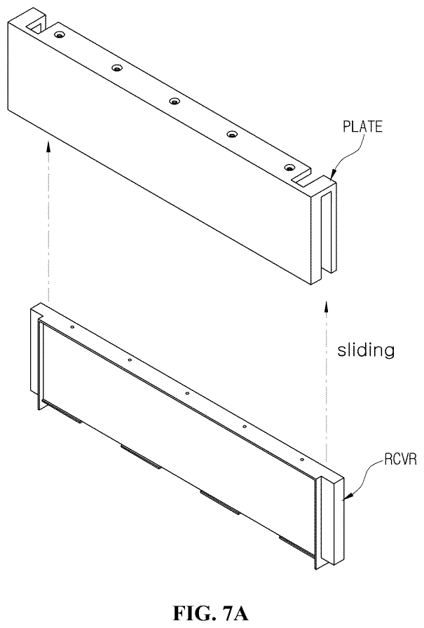

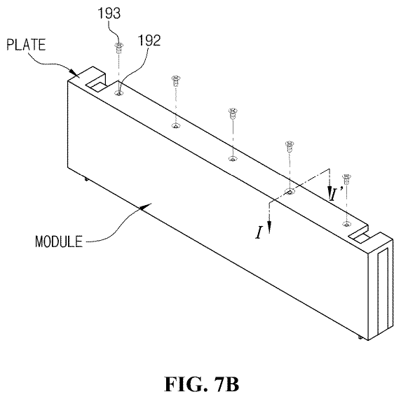

FIGS. 7A and 7B are views illustrating coupling of the display module MODULE to the rear cover RCVR.

First, as shown in FIG. 7A, the guide groove 184 of the display module MODULE is open downward, and the guide bar BAR of the rear cover RCVR is slidably coupled to the guide groove 184 by pushing the rear cover RCVR upward while the rear cover RCVR is inserted into the guide groove 184.

After the guide bar BAR of the rear cover RCVR is inserted into the guide groove 184 of the plate PLATE, the guide bar BAR slides along the guide groove 184 until the upper surface 120T of the rear cover RCVR reaches the lower surface of the protrusion 186 of the plate PLATE.

Thereafter, as shown in FIG. 7B, a screw 194 is inserted into the screw hole 192 formed in the upper part of the protrusion 186 to screw the protrusion 186 and the upper surface of the rear cover RCVR together in order to couple the rear cover RCVR and the display module MODULE. At this time, although not shown in the drawing, a screw hole is formed in the area corresponding to the screw hole 192 of the upper surface of the rear cover RCVR, so that they can be coupled by the screw 194.

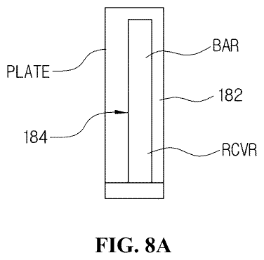

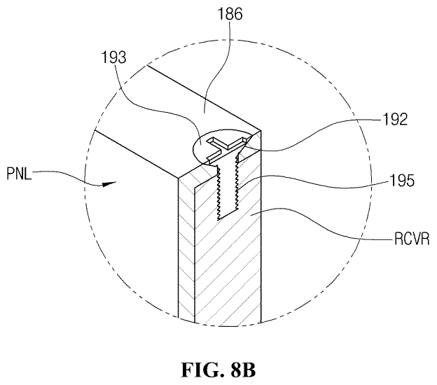

FIGS. 8A and 8B are views illustrating a coupling portion of the display module MODULE and the set frame SETFRM of the display apparatus 100 according to the present application, and FIG. 8B is a partially enlarged cross-sectional view taken along line I-I′ of FIG. 8A.

As shown in FIG. 8A, the guide grooves 184 are formed on both sides of the rear surface of the plate PLATE, and the guide bar BAR of the rear cover RCVR of the set frame SETFRM is slidably inserted into the guide groove 184 so that the plate PLATE and the rear cover RCVR are primarily coupled to each other.

As shown in FIG. 8B, when the guide bar BAR of the rear cover RCVR of the set frame SETFRM is slidably inserted into the guide groove 184 of the plate PLATE, the upper surface 120T (FIG. 5) of the rear cover RCVR is contacted with the lower surface of the protrusion 186 of the plate PLATE, so that the first screw hole 192 formed in the protrusion 186 of the plate PLATE and the second screw hole 195 formed in the upper surface 120T of the rear cover RCVR are aligned with each other. Thereafter, the screw 193 is inserted into the first screw hole 192 and the second screw hole 195, so that the plate PLATE and the rear cover RCVR are secondarily coupled.

At this time, a plurality of first screw holes 192 and second screw holes 195 are respectively formed in the protrusion 186 of the plate PLATE and the upper surface 120T of the rear cover RCVR to firmly couple the plate PLATE and the rear cover RCVR.

As described above, in the present application, since the plate PLATE and the rear cover RCVR are first coupled by sliding insertion and secondarily coupled by screws to couple finally the display module MODULE and the set frame SETFRM, it is possible to firmly combine the display module MODULE and the set frame SETFRM.

Further, in this application, since the display module MODULE and the set frame SETFRM are combined by sliding insertion and screws, the assembly of the display apparatus 100 is easy and quick.

In addition, in this application, since the display module MODULE and the set frame SETFRM can be disassembled, the display module MODULE can be reused.

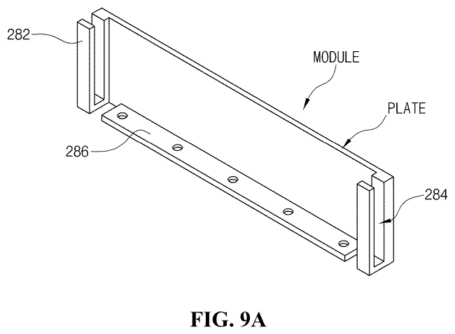

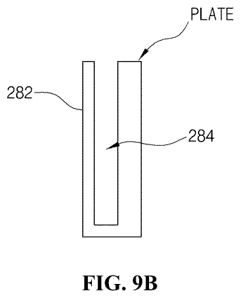

FIGS. 9A and 9B are the views illustrating the display module MODULE of the display apparatus according to a second embodiment of the present application. In this case, since the difference between the display apparatus according to the first embodiment and the display apparatus according to the second embodiment is the coupling structure between the entrance of the guide groove, the plate, and the rear cover, only the different structure will be described in detail and other structures will be omitted or briefly described.

As shown in FIGS. 9A and 9B, the display panel PNL is attached to the front surface of the plate PLATE by an adhesive, and the guide member 282 is disposed on the rear surface. The guide member 282 is installed at both ends of the rear surface of the plate PLATE to form a guide groove 284, which is an empty space between the guide member 282 and the rear surface of the plate PLATE. In this case, the guide member 282 is connected to the lower surface of the plate PLATE, so that the guide groove 284 has an entrance formed at the upper end of the plate PLATE. That is, the open entrance of the guide groove is formed at the lower end of the plate PLATE in the first embodiment, whereas the open entrance of the guide groove is formed at the upper end of the plate PLATE in this embodiment.

The protrusion 286 disposed perpendicular to the plate PLATE is formed at the lower end of the rear surface of the plate PLATE.

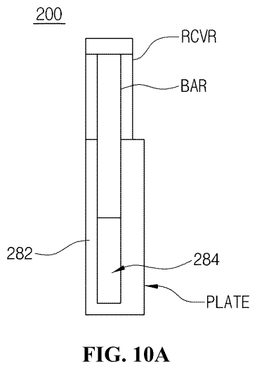

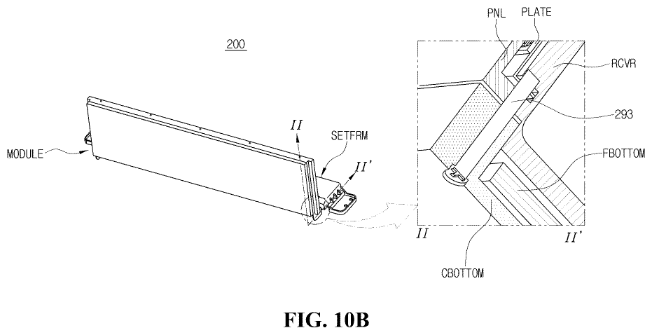

FIGS. 10A and 10B are views illustrating coupling portions of the display module MODULE and the set frame SETFRM of the display apparatus according to the second embodiment of the present application, respectively, and FIG. 10A is the side view of the display apparatus 200 and FIG. 10B is the partially enlarged cross-sectional view taken along a line II-II″.

As shown in FIG. 10A, the guide grooves 284 are formed at both side ends of the rear surface of the plate PLATE, and the guide bar BAR of the rear cover RCVR of the set frame SETFRM is slidably inserted into the guide bar BAR from the upper side of the plate PLATE so that the plate PLATE and the rear cover RCVR are primarily coupled.

As shown in FIG. 10B, when the guide bar BAR of the rear cover RCVR of the set frame SETFRM is slidably inserted into the guide groove 284 of the plate PLATE, the lower surface of the rear cover RCVR is contacted with the upper surface of the protrusion 286 of the plate PLATE. Further, the protrusion 286 of the plate PLATE is contacted with the cover inverter CBOTTOM.

That is, when the guide bar BAR of the rear cover RCVR of the set frame SETFRM is slidably inserted into the guide groove 284 of the plate PLATE, the bottom surface of the rear cover RCVR is contacted with the protrusion 286 of the plate PLATE and the top surface of the cover bottom CBOTTOM, and in this state the screw 293 is inserted into the cover bottom CBOTTOM, the rear cover RCVR, and the protrusion 286 of the plate PLATE to secondarily couple the plate PLATE and the rear cover RCVR.

As described above, since the display module MODULE and the set frame SETFRM are combined by the primary coupling by sliding insertion and the secondary coupling by screws, it is possible to firmly combine the display module MODULE and the set frame SETFRM.

The above description and the accompanying drawings are merely illustrative of the technical idea of the present disclosure, and those of ordinary skill in the art to which the present disclosure pertains can combine configurations within a range that does not depart from the essential characteristics of the present disclosure, various modifications or variations such as separation, substitution and alteration will be possible. Therefore, the embodiments disclosed in the present disclosure are not intended to limit the technical idea of the present disclosure, but to explain, and the scope of the technical idea of the present disclosure is not limited by these embodiments.

What is claimed is:

1. A display apparatus, comprising:
a display panel;
a plate of which a front surface is attached to the display panel;
a plurality of guide members disposed on both side ends of a rear surface of the plate to form a plurality of guide grooves between each of the plurality of guide members and the rear surface of the plate;
a plurality of protrusions formed in the plate;
a rear cover disposed on the rear surface of the plate;
a plurality of guide bars formed on both sides of the rear cover configured to be slidingly inserted into the guide grooves so as to assemble the plate and the rear cover; and
a plurality of coupling members for coupling each of the plurality of protrusions and the rear cover.

2. The display apparatus of claim 1, wherein the plate and each of the plurality of guide members are integrally formed.

3. The display apparatus of claim 2, wherein each of the plurality of guide members is connected to an upper end of the rear surface of the plate.

4. The display apparatus of claim 3, wherein an entrance of each of the plurality of guide grooves is formed under the plate so that the rear cover is inserted into each of the plurality of guide grooves from a bottom of the guide groove.

5. The display apparatus of claim 4, wherein each of the plurality of protrusions is formed in the upper end of the rear surface of the plate.

6. The display apparatus of claim 5, wherein each of the plurality of coupling members is a first screw penetrating the plate and an upper surface of the rear cover.

7. The display apparatus of claim 3, wherein an entrance of each of the plurality of guide grooves is formed above the plate so that the rear cover is inserted into the guide groove from a top of the guide groove.

8. The display apparatus of claim 7, wherein each of the plurality of protrusions is formed in a lower end of the rear surface of the plate.

9. The display apparatus of claim 8, wherein each of the plurality of coupling members is a second screw penetrating the plate and a lower surface of the rear cover.

10. The display apparatus of claim 9, further comprising:
a frame bottom disposed under the rear cover; and
a cover bottom coupled to the frame bottom.

11. The display apparatus of claim 10, wherein the second screw penetrates the cover bottom.

12. The display apparatus of claim 1, wherein the display panel is attached to the front surface of the plate by an adhesive.

13. The display apparatus of claim 1, wherein the display panel comprises a liquid crystal display panel, an organic light emitting display panel, a mini-LED display panel, an electrophoretic display panel, or a micro-LED display panel.
